(19) United States
(12) Patent Application Publication
(10) Pub. No.: US 2026/0101727 A1
(43) Pub. Date: Apr. 9, 2026

(54) METHODS OF FORMING SEMICONDUCTOR STRUCTURES

(71) Applicant: NANYA TECHNOLOGY CORPORATION, New Taipei City (TW)

(72) Inventor: Wei-Chuan FANG, New Taipei City (TW)

(21) Appl. No.: 18/911,056

(22) Filed: Oct. 9, 2024

(51) Int. Cl. H01L 21/033; H01L 21/311

(52) U.S. Cl. CPC H10P 76/405; H10D 1/692; H10P 50/282

(57) ABSTRACT

The present disclosure provides a method of forming a semiconductor structure. The method includes the following operations. A diamond-like carbon hard mask layer is formed on a substrate, in which an absorbance of the diamond-like carbon hard mask layer is smaller than or equal to 0.5. A dielectric anti-reflective coating layer is formed on the diamond-like carbon hard mask layer. A bottom anti-reflective coating layer is formed on the dielectric anti-reflective coating layer.

### BACKGROUND

### Field of Invention

The present disclosure relates to methods of forming semiconductor structures.

### Description of Related Art

A Kodiak carbon hard mask is known to be the hardest hard mask layer in the semiconductor manufacturing processes. However, disadvantages of using the Kodiak carbon hard mask include having too thick of the Kodiak carbon hard mask, low transmittance and high absorbance of the Kodiak carbon hard mask, and so on. As etching to form the semiconductor structure with a higher aspect ratio, the thickness of the Kodiak carbon hard mask must become larger and larger. The thicker Kodiak carbon hard mask makes the transmittance of the Kodiak carbon hard mask poorer, resulting in less light reflected from the Kodiak carbon hard mask when using the light to find the accurate position for performing the etching. Once an incorrect position is found to perform the etching, such etching may damage the semiconductor structure, and obtaining a high aspect ratio of the semiconductor structure may also fail. Therefore, a new method of forming the semiconductor structure should be developed to meet more expectations.

### SUMMARY

The present disclosure provides a method of forming a semiconductor structure. The method includes the following operations. A diamond-like carbon hard mask layer is formed on a substrate, in which an absorbance of the diamond-like carbon hard mask layer is smaller than or equal to 0.5. A dielectric anti-reflective coating layer is formed on the diamond-like carbon hard mask layer. A bottom anti-reflective coating layer is formed on the dielectric anti-reflective coating layer.

In some embodiments, forming the diamond-like carbon hard mask layer includes: providing C₂H₂ and an inert gas; and reacting the C₂H₂ to form the diamond-like carbon hard mask layer.

In some embodiments, a ratio of a flow rate of the C₂H₂ to a flow rate of the inert gas is from 1:20 to 1:50.

In some embodiments, a flow rate of the C₂H₂ is from 290 SCCM to 390 SCCM.

In some embodiments, forming the diamond-like carbon hard mask layer is performed at a pressure from 1.3 Torr to 3.1 Torr.

In some embodiments, forming the diamond-like carbon hard mask layer is performed at a temperature from 150° C. to 400° C.

In some embodiments, a stress of the diamond-like carbon hard mask layer is from −750 MPa to −350 MPa.

In some embodiments, a thickness of the diamond-like carbon hard mask layer is smaller than or equal to 150 nm.

In some embodiments, an etch selectivity of an oxide material relative to the diamond-like carbon hard mask layer is from 15:1 to 25:1.

The present disclosure also provides a method of forming a semiconductor structure. The method includes the following operations. An amorphous carbon hard mask layer is formed on first electrodes of capacitors on a substrate, in which an absorbance of the amorphous carbon hard mask layer is smaller than or equal to 0.5, and an oxide layer is disposed between the first electrodes of the capacitors. A photoresist layer having an opening is formed on the amorphous carbon hard mask layer. The amorphous carbon hard mask layer is etched through the opening of the photoresist layer.

In some embodiments, etching the amorphous carbon hard mask layer is performed till the oxide layer disposed between the first electrodes of the capacitors is exposed, and the method further includes etching the oxide layer and forming dielectric layers and second electrodes on the first electrodes.

In some embodiments, the method further includes before or during forming the photoresist layer having the opening on the amorphous carbon hard mask layer, using a light shining on and reflecting from the amorphous carbon hard mask layer to determine positions of the first electrodes for aligning the opening of the photoresist layer with a position between two of the first electrodes.

In some embodiments, etching the amorphous carbon hard mask layer includes using an anisotropic dry etching method.

In some embodiments, a stress of the amorphous carbon hard mask layer is from −750 MPa to −350 MPa.

In some embodiments, a thickness of the amorphous carbon hard mask layer is smaller than or equal to 150 nm.

### BRIEF DESCRIPTION OF THE DRAWINGS

The present disclosure can be more fully understood by reading the following detailed description of the embodiments, with reference made to the accompanying drawings.

FIG. 1 is a flow chart of a method of forming a semiconductor structure according to some embodiments of the present disclosure.

FIGS. 2 to 3 are schematic cross-sectional diagrams of the structures in the process of using a method of forming a semiconductor structure according to some embodiments of the present disclosure.

FIG. 4 is a flow chart of a method of forming a semiconductor structure according to some embodiments of the present disclosure.

FIGS. 5 to 10 are schematic cross-sectional diagrams of the structures in the process of using a method of forming a semiconductor structure according to some embodiments of the present disclosure.

FIG. 11 is a schematic cross-sectional diagram of the structures in the process of using a method of forming a semiconductor structure according to a comparative embodiment of the present disclosure.

### DETAILED DESCRIPTION

To make the description of the present disclosure detailed and complete, the following is an illustrative description of the aspects of the embodiments. This is not to limit the embodiments of the present disclosure to only one form. The embodiments of the present disclosure may be combined or substituted with each other when it is beneficial, and other embodiments may be added without further explanation.

In addition, spatially relative terms, such as below and above, etc., may be used in the present disclosure to describe the relationship between one element (or feature) to another element (or feature) in the figures. In addition to the orientation depicted in the figures, spatially relative terms are intended to encompass different orientations of the device in use or in operation. For example, the device may be oriented otherwise (e.g., rotated 90 degrees), and the spatially relative terms can be interpreted accordingly. In the present disclosure, unless otherwise indicated, the same element numbers in different figures refer to the same or similar elements formed from the same or similar materials by the same or similar methods.

The terms “around”, “approximately”, “nearly”, “basically”, “substantially”, etc., used in the present disclosure include the stated values (or characteristics) and a deviation of the stated values (or characteristics) understood by one skilled in the art. For example, considering the errors of the values (or characteristics), these terms may indicate the values within one or more standard deviations (e.g., the values within ±30%, ±20%, ±15%, ±10%, or ±5%), or may indicate the characteristics including the deviation from the practical operation (e.g., the “substantially parallel” may indicate close to parallel in practical, rather than a perfect ideally parallelism). Furthermore, it is possible to select an acceptable range of the deviation according to the nature of the measurement or other properties, instead of applying only one single deviation range to all the values (or characteristics).

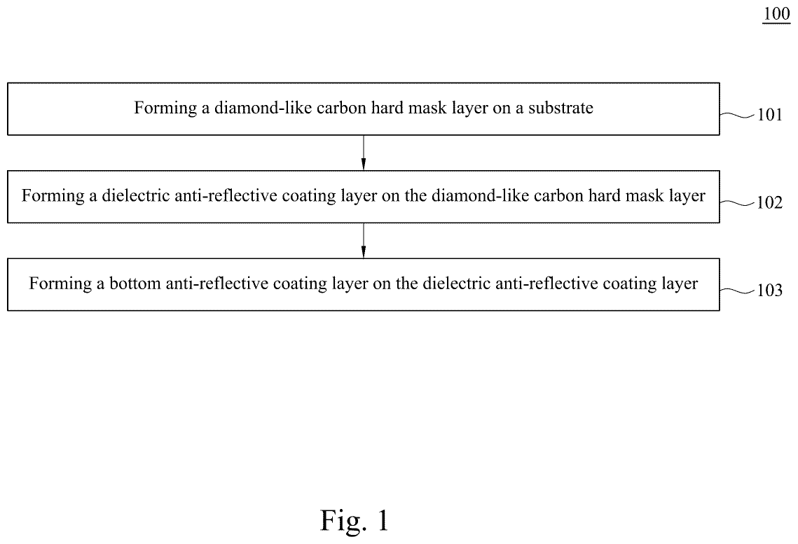

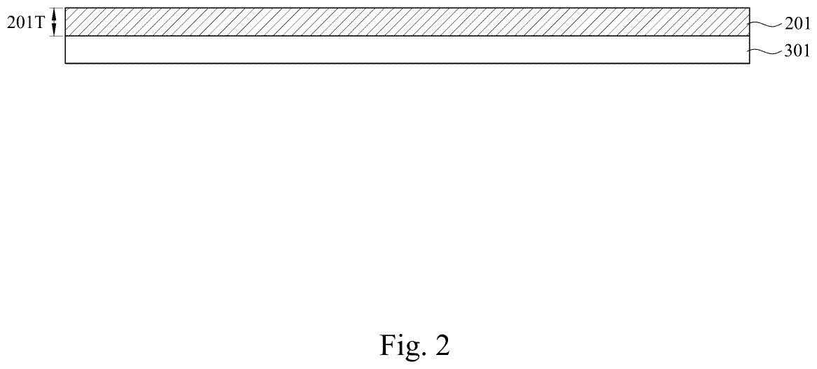

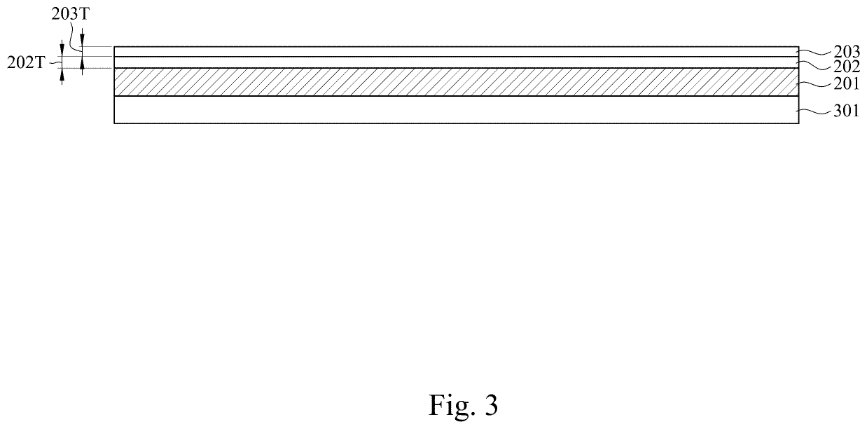

The present disclosure provides a method 100 of forming a semiconductor structure, as shown in FIG. 1. The semiconductor structure includes stacked layers used as an etch mask to apply on any suitable component in the semiconductor structure, in order to perform a more accurate semiconductor etching process to form the improved semiconductor structure. FIGS. 2 to 3 are schematic cross-sectional diagrams of the structural changes when using the method 100. The method 100 includes an operation 101 to an operation 103. The operation 101 includes forming a diamond-like carbon hard mask layer 201 on a substrate 301, in which an absorbance of the diamond-like carbon hard mask layer 201 is smaller than or equal to 0.5. The operation 102 includes forming a dielectric anti-reflective coating layer 202 on the diamond-like carbon hard mask layer 201. The operation 103 includes forming a bottom anti-reflective coating layer 203 on the dielectric anti-reflective coating layer 202. The diamond-like carbon hard mask layer 201, the dielectric anti-reflective coating layer 202, and the bottom anti-reflective coating layer 203 are together used as an improved etch mask on the substrate 301, in order to etch the substrate 301 for higher etch quality, for example, a higher aspect ratio in the etched pattern, reducing damage and wobbling in the etched pattern, and so on, thereby improving the performance of the substrate 301 after performing the etching. Next, the method 100 is described in detail by the embodiments provided in the present disclosure.

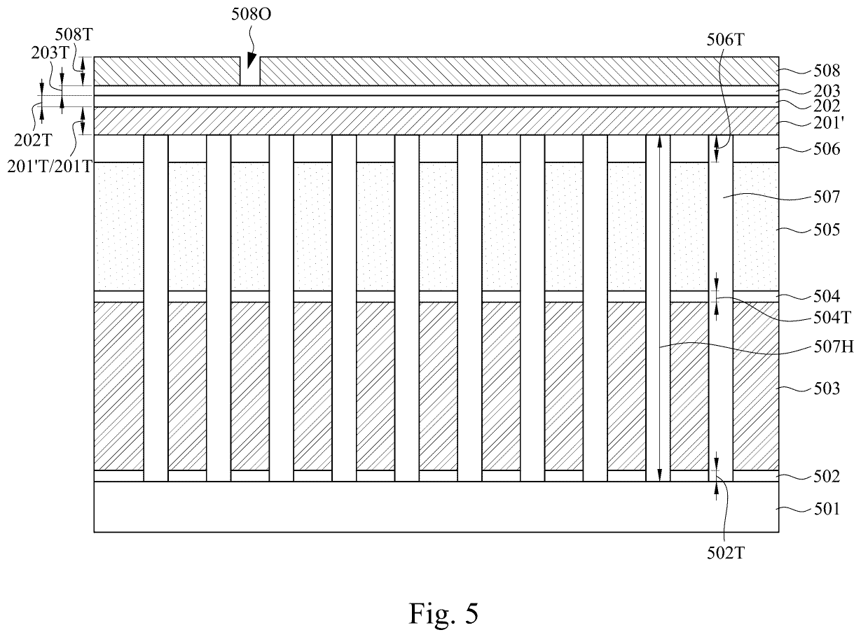

In some embodiments, the substrate 301 is configured to be etched by any suitable following operation. In some embodiments, an example of the substrate 301 may be those shown in FIG. 5, including the first electrodes 507 arranged in the oxide layers and supported by the nitride layers, and so on. Details of FIG. 5 are provided in the following description, and please refer to the following description. However, the present disclosure does not limit the substrate 301 as those provided in FIG. 5, and the etch mask in the present disclosure can apply to any suitable component in the semiconductor structure. In some embodiments, the substrate 301 is a semiconductor substrate and may include a semiconductor material. In some embodiments, the semiconductor material includes an elemental semiconductor material, for example, carbon, monocrystalline silicon, polycrystalline silicon, amorphous silicon, germanium, tin, sulfur, selenium, tellurium, or the like; a compound semiconductor material, for example, silicon carbide, nitride boron, aluminum nitride, gallium nitride, gallium phosphide, gallium arsenide, indium phosphide, indium arsenide, indium antimonide, zinc oxide, or the like; an alloy semiconductor material, for example, SiGe, AlGaAs, InGaAs, InGaP, AlInAs, GaAsP, AlGaN, InGaN, AlGaInP, or the like; or combinations thereof.

The diamond-like carbon hard mask layer 201 has a structure similar to a diamond to improve the hardness of the diamond-like carbon hard mask layer 201 when the diamond-like carbon hard mask layer 201 is used as an etch hard mask. In addition, the absorbance of the diamond-like carbon hard mask layer 201 is preferably smaller than or equal to 0.5, for example, from 0.3 to 0.5, e.g., 0.3, 0.35, 0.4, 0.45, or 0.5, to avoid light being absorbed too much by the diamond-like carbon hard mask layer 201 and failing to be reflected from the diamond-like carbon hard mask layer 201. Therefore, when the diamond-like carbon hard mask layer 201 is applied to etch the substrate 301, one can use the light shining on and reflected from the semiconductor structure to find a correct etch position where the etching should be performed. Taking FIG. 5 as an example, light (e.g., the angle and/or the intensity) reflected from the first electrodes 507 and the second oxide layer 505 after shining the light on the first electrodes 507 and the second oxide layer 505 may be different, so the correct etch position may be found for etching the second oxide layer 505 rather than damaging the first electrodes 507 and/or rather than causing the first electrodes 507 to bend after the etching. In some embodiments, a transmittance of the diamond-like carbon hard mask layer 201 is preferably larger than or equal to 0.5, for example, from 0.5 to 0.7, e.g., 0.5, 0.55, 0.6, 0.65, or 0.7, to avoid light being absorbed too much by the diamond-like carbon hard mask layer 201 and failing to be reflected from the diamond-like carbon hard mask layer 201. In some embodiments, a refractive index of the diamond-like carbon hard mask layer 201 is preferably from 1.80 to 2.00, for example, 1.80, 1.85, 1.90, 1.95, or 2.00, to provide a suitable refraction of the light, in order to increase the accuracy of finding the correct etch position. In some embodiments, the absorbance, the transmittance, and the refractive index are measured at a wavelength of light from 230 nm to 260 nm, for example, 230 nm, 240 nm, 250 nm, or 260 nm.

In some embodiments, the diamond-like carbon hard mask layer 201 includes amorphous carbon. In some embodiments, in carbon-carbon bonds of the diamond-like carbon hard mask layer 201, an amount of sp³ hybridization is preferably from 25% to 29%, for example, 25%, 26%, 27%, 28%, or 29%, to provide the diamond-like carbon hard mask layer 201 with sufficiently high hardness and low stress, thereby ensuring that the etch pattern is transferred as expected shape and size and the structure is not bent easily when using the diamond-like carbon hard mask layer 201 as the etch hard mask to perform the etching. In some embodiments, the stress of the diamond-like carbon hard mask layer 201 is preferably from −750 MPa to −350 MPa, for example, −750 MPa, −650 MPa, −550 MPa, −450 MPa, or −350 MPa, to avoid the stress being too low to cause the hardness of the diamond-like carbon hard mask layer 201 to decrease accordingly and to avoid the stress being too high. In some embodiments, the diamond-like carbon hard mask layer 201 is different than the hard mask made from Kodiak carbon. In some embodiments, since the diamond-like carbon hard mask layer 201 is hard enough and absorbs less light, a thickness 201T of the diamond-like carbon hard mask layer 201 can be smaller to save the cost. For example, a thickness 201T of the diamond-like carbon hard mask layer 201 is preferably smaller than or equal to 150 nm, for example, from 50 nm to 150 nm, e.g., 50 nm, 70 nm, 90 nm, 110 nm, 130 nm, or 150 nm.

In some embodiments, an etch selectivity of an oxide material relative to the diamond-like carbon hard mask layer 201 (i.e., a ratio of an etch rate of the oxide material to an etch rate of the diamond-like carbon hard mask layer 201) is preferably from 15:1 to 25:1, for example, 15:1, 17.5:1, 20:1, 22.5:1, or 25:1, to ensure that the diamond-like carbon hard mask layer 201 is more resistant to be etched than the oxide material for being the etch hard mask to etch the oxide material with a higher etch quality. In some embodiments, the oxide material includes a common oxide layer used in various semiconductor processes, for example, silicon oxide, tetraethoxysilane, borophosphosilicate glass, or combinations thereof.

In some embodiments, in the operation 101, forming the diamond-like carbon hard mask layer 201 is performed by using plasma, for example, by a plasma-enhanced chemical vapor deposition. In some embodiments, forming the diamond-like carbon hard mask layer 201 includes using C₂H₂ to be a precursor and an inert gas to be a carrier gas and/or to increase the collision to the C₂H₂ for increasing the ionization of the C₂H₂. In some embodiments, the inert gas includes He, Ar, or a combination thereof. In some embodiments, a ratio of a flow rate of the C₂H₂ to a flow rate of the inert gas is preferably from 1:20 to 1:50, for example, 1:20, 1:30, 1:40, or 1:50. If the flow rate of the C₂H₂ is too large or too small, the desired diamond-like carbon hard mask layer 201 may not be formed successfully. If the flow rate of the inert gas is too large or too small, the collision to the C₂H₂ may be too strong or too small to influence the formed diamond-like carbon hard mask layer 201 and/or the efficiency of forming the diamond-like carbon hard mask layer 201 may decrease. In some embodiments, the flow rate of the C₂H₂ is preferably from 290 SCCM to 390 SCCM, for example, 290 SCCM, 310 SCCM, 330 SCCM, 350 SCCM, 370 SCCM, or 390 SCCM.

In some embodiments, the plasma formed from the C₂H₂ and/or the inert gas is generated by using an electromagnetic wave with a low frequency and an electromagnetic wave with a high frequency. In some embodiments, the high frequency is larger than the low frequency. In some embodiments, the low frequency is preferably from 30 Hz to 300 KHz, for example, 30 Hz, 100 Hz, 500 Hz, 1000 Hz, 5000 Hz, 10000 Hz, 50000 Hz, 100000 Hz, 200000 Hz, or 300000 Hz. In some embodiments, the high frequency is preferably from 3 MHz to 30 MHz, for example, 3 MHz, 10 MHz, 15 MHz, 20 MHz, 25 MHz, or 30 MHz. In some embodiments, the high frequency includes a radio frequency. In some embodiments, a power to generate the low frequency is preferably from 1500 W to 3000 W, for example, 1500 W, 1750 W, 2250 W, 2500 W, 2750 W, or 3000 W. In some embodiments, a power to generate the high frequency is preferably from 100 W to 800 W, for example, 100 W, 250 W, 500 W, 650 W, or 800 W.

In some embodiments, forming the diamond-like carbon hard mask layer 201 is performed at a pressure preferably from 1.3 Torr to 3.1 Torr, for example, 1.3 Torr, 2.0 Torr, 2.5 Torr, or 3.1 Torr. In some embodiments, forming the diamond-like carbon hard mask layer 201 is performed at a temperature preferably from 150° C. to 400° C., for example, 150° C., 200° C., 250° C., 300° C., 350° C., or 400° C.

In the operation 102, forming the dielectric anti-reflective coating layer 202 includes any suitable method, for example, a chemical vapor deposition or a physical vapor deposition. In some embodiments, the dielectric anti-reflective coating layer 202 is an O-rich dielectric anti-reflective coating layer to decrease an absorbance of the dielectric anti-reflective coating layer 202 compared to an absorbance of a Si-rich dielectric anti-reflective coating layer. In some embodiments, an oxygen atomic ratio is larger than a silicon atomic ratio in the O-rich dielectric anti-reflective coating layer. In some embodiments, the silicon atomic ratio in the O-rich dielectric anti-reflective coating layer is preferably smaller than 50%. In some embodiments, the dielectric anti-reflective coating layer 202 includes silicon oxynitride. In some embodiments, a thickness 202T of the dielectric anti-reflective coating layer 202 is preferably from 25 nm to 45 nm, for example, 25 nm, 35 nm, or 45 nm.

In the operation 103, forming the bottom anti-reflective coating layer 203 includes any suitable method, for example, a chemical vapor deposition or a physical vapor deposition. In some embodiments, the bottom anti-reflective coating layer 203 includes an organic material. In some embodiments, a refractive index of the bottom anti-reflective coating layer 203 is similar to or the same as a refractive index of the dielectric anti-reflective coating layer 202 to reduce the reflected light when performing photolithography on the photoresist layer (e.g., the photoresist layer 508 described below) disposed on the bottom anti-reflective coating layer 203. In some embodiments, a thickness 203T of the bottom anti-reflective coating layer 203 is preferably from 1 nm to 10 nm, for example, 1 nm, 2.5 nm, 5 nm, 7.5 nm, or 10 nm.

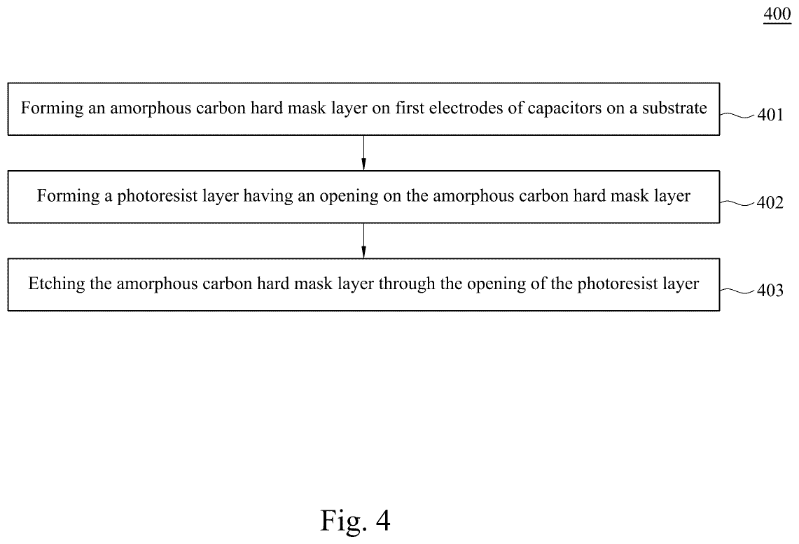

The present disclosure also provides a method 400 of forming a semiconductor structure, as shown in FIG. 4. The method 400 uses an amorphous carbon hard mask layer (e.g., the diamond-like carbon hard mask layer 201 described above) as the etch hard mask to etch the component disposed below the amorphous carbon hard mask layer, as shown in FIG. 5, and FIGS. 5 to 10 are schematic cross-sectional diagrams of the structural changes when using the method 400. The method 400 includes an operation 401 to an operation 403. The operation 401 includes forming the amorphous carbon hard mask layer 201′ on first electrodes 507 of capacitors on a substrate 501, in which an absorbance of the amorphous carbon hard mask layer 201′ is smaller than or equal to 0.5. The operation 402 includes forming a photoresist layer 508 having an opening 508O on the amorphous carbon hard mask layer 201′. The operation 403 includes etching the amorphous carbon hard mask layer 201′ through the opening 508O of the photoresist layer 508. Next, the method 400 is described in detail by the embodiments provided in the present disclosure.

In FIG. 5, the amorphous carbon hard mask layer 201′ is formed on the first electrodes 507 of the capacitors on the substrate 501 in the operation 401. In some embodiments, the amorphous carbon hard mask layer 201′ is the diamond-like carbon hard mask layer 201 described above, so the details including the material, the absorbance, the transmittance, the refractive index, the amount of sp³ hybridization, the stress, the thickness 201′T, the forming method, and so on of the amorphous carbon hard mask layer 201′ are not repeated herein, and the details can be referred to the description above. In some embodiments, the substrate 501, a first nitride layer 502, a first oxide layer 503, a second nitride layer 504, a second oxide layer 505, a third nitride layer 506, and the first electrodes 507 are disposed below the amorphous carbon hard mask layer 201′, and the amorphous carbon hard mask layer 201′ is used as the etch hard mask to etch a portion of the third nitride layer 506, in order to further etch the second oxide layer 505, the second nitride layer 504, and the first oxide layer 503 in the following operations to expose surfaces of the first electrodes 507. Once the surfaces of the first electrodes 507 are exposed, dielectric layers 509 and second electrodes 510 may form on the first electrodes 507 to form the capacitors. In some embodiments, the substrate 501, the first nitride layer 502, the first oxide layer 503, the second nitride layer 504, the second oxide layer 505, the third nitride layer 506, and the first electrodes 507 together can be the substrate 301 described above.

In some embodiments, the substrate 501 includes a semiconductor material. In some embodiments, the semiconductor material includes an elemental semiconductor material, for example, carbon, monocrystalline silicon, polycrystalline silicon, amorphous silicon, germanium, tin, sulfur, selenium, tellurium, or the like; a compound semiconductor material, for example, silicon carbide, nitride boron, aluminum nitride, gallium nitride, gallium phosphide, gallium arsenide, indium phosphide, indium arsenide, indium antimonide, zinc oxide, or the like; an alloy semiconductor material, for example, SiGe, AlGaAs, InGaAs, InGaP, AlInAs, GaAsP, AlGaN, InGaN, AlGaInP, or the like; or combinations thereof. In some embodiments, the substrate 501 includes metal, for example, tungsten.

In some embodiments, the first electrodes 507 are disposed on the substrate 501. In some embodiments, the first electrodes 507 extend along the direction perpendicular to the surface of the substrate 501 to increase the aspect ratios and/or the integrated density of the capacitors on the substrate 501. In some embodiments, a height 507H of each one of the first electrodes 507 (or each one of the capacitors) is preferably from 850 nm to 1250 nm, for example, 850 nm, 950 nm, 1050 nm, 1150 nm, or 1250 nm. In some embodiments, the first electrodes 507 form a two-dimensional array on the substrate 501. In some embodiments, one of the first electrodes 507 (or the capacitors) is separated from another one of the first electrodes 507 (or the capacitors) to avoid current leakage. In some embodiments, the first electrodes 507 include a metal. In some embodiments, the first electrodes 507 include TiSiN.

In some embodiments, the first nitride layer 502, the second nitride layer 504, and the third nitride layer 506 are disposed beside the bottom, the middle, and the top of the first electrodes 507, respectively, to provide structural support to the first electrodes 507. In some embodiments, the first nitride layer 502, the second nitride layer 504, and the third nitride layer 506 are silicon nitride. In some embodiments, a thickness 502T of the first nitride layer 502, a thickness 504T of the second nitride layer 504, and a thickness 506T of the third nitride layer 506 are preferably from 10 nm to 100 nm, for example, 10 nm, 20 nm, 30 nm, 40 nm, 60 nm, 80 nm, or 100 nm.

In some embodiments, the first oxide layer 503 and the second oxide layer 505 are used as mold layers to form the first electrodes 507, and the first oxide layer 503 and the second oxide layer 505 will be removed in the following operation to expose the surfaces of the first electrodes 507 for forming the dielectric layers 509 and the second electrodes 510. In some embodiments, although not shown in the cross-sectional view of FIG. 5, the first oxide layer 503 extends continually between the first electrodes 507, and the second oxide layer 505 extends continually between the first electrodes 507, so as long as a portion of the first oxide layer 503 is removed and a portion of the second oxide layer 505 is removed, the whole first oxide layer 503 and the whole second oxide layer 505 may be removed together, for example, by a wet etching process. In some embodiments, the first oxide layer 503 is disposed between the first nitride layer 502 and the second nitride layer 504, and the second oxide layer 505 is disposed between the second nitride layer 504 and the third nitride layer 506. In some embodiments, the first oxide layer 503 and the second oxide layer 505 include silicon oxide, tetraethoxysilane, borophosphosilicate glass, or combinations thereof.

In some embodiments, before performing the operation 402, the method 400 further includes forming the dielectric anti-reflective coating layer 202 on the amorphous carbon hard mask layer 201′ and forming the bottom anti-reflective coating layer 203 on the dielectric anti-reflective coating layer 202 to increase the accuracy of performing the photolithography on the photoresist layer 508 described below and thus increase the accuracy of performing the etching to the component disposed below the amorphous carbon hard mask layer 201′. Details of the dielectric anti-reflective coating layer 202 and the bottom anti-reflective coating layer 203 are not repeated herein, and the details can be referred to the description above.

In FIG. 5, the photoresist layer 508 having the opening 508O is formed on the amorphous carbon hard mask layer 201′ in the operation 402. The opening 508O defines where the etch position is. In some embodiments, the opening 508O is disposed above a portion of the second oxide layer 505 between two adjacent ones of the first electrodes 507. In some embodiments, the method 400 further includes forming the opening 508O of the photoresist layer 508 by a suitable photolithography method. In some embodiments, before or during forming the opening 508O of the photoresist layer 508, the method 400 further includes using a light shining on and reflecting from the component disposed below the photoresist layer 508 to determine positions of the first electrodes 507, in order to make the opening 508O of the photoresist layer 508 be aligned with a position between two adjacent ones of the first electrodes 507 when forming the opening 508O of the photoresist layer 508. Since the component disposed below the photoresist layer 508 includes the amorphous carbon hard mask layer 201′ having a smaller absorbance, the light shining on and reflected from the amorphous carbon hard mask layer 201′ is measurable to find the correct etch position. In some embodiments, the numbers of the opening 508O of the photoresist layer 508 are not limited. In some embodiments, a thickness 508T of the photoresist layer 508 is preferably from 80 nm to 120 nm, for example, 80 nm, 90 nm, 100 nm, 110 nm, or 120 nm.

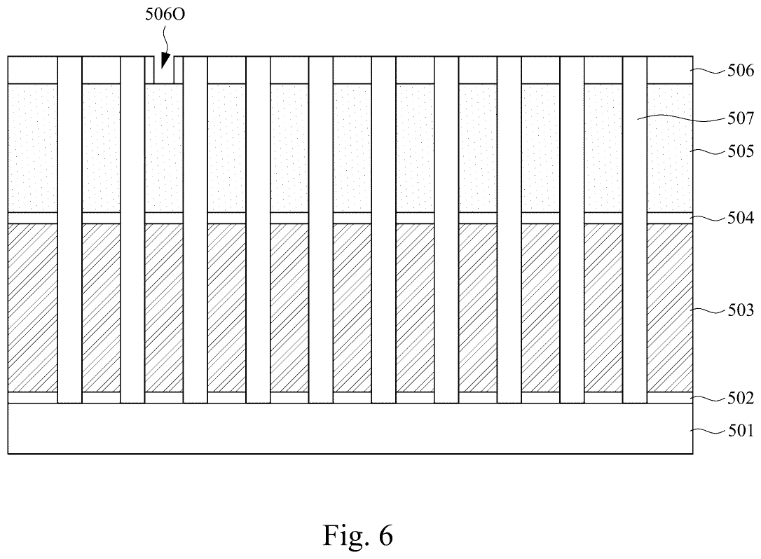

In FIG. 6, the amorphous carbon hard mask layer 201′ is etched through the opening 508O of the photoresist layer 508 in the operation 403. In some embodiments, the etching to etch the amorphous carbon hard mask layer 201′ is performed till the second oxide layer 505 is exposed. In some embodiments, the etching includes transforming the pattern of the opening 508O of the photoresist layer 508 to the amorphous carbon hard mask layer 201′ and further to the third nitride layer 506, such that a portion of the third nitride layer 506 is etched to form an opening 506O of the third nitride layer 506, as shown in FIG. 6. In some embodiments, a width of the opening 508O of the photoresist layer 508 is substantially equal to a width of the opening 506O of the third nitride layer 506. In some embodiments, when the second oxide layer 505 is exposed by the opening 506O of the third nitride layer 506, the components disposed above the third nitride layer 506, including the amorphous carbon hard mask layer 201′, may have been etched completely. In some embodiments, if the components disposed above the third nitride layer 506, including the amorphous carbon hard mask layer 201′, are not etched completely after the second oxide layer 505 is exposed when the opening 506O of the third nitride layer is formed, the method 400 may further includes removing the components disposed above the third nitride layer 506, including removing the amorphous carbon hard mask layer 201′. In some embodiments, the etching is performed preferably by an anisotropic dry etching method.

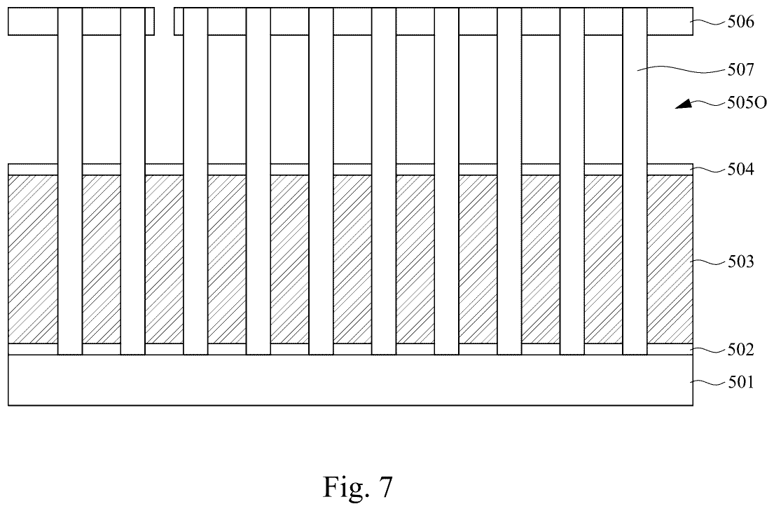

In FIG. 7, the method 400 further includes etching the second oxide layer 505 through the opening 506O of the third nitride layer 506. After etching the second oxide layer 505, an opening 505O between the first electrodes 507 is formed to expose the surfaces of the first electrodes 507 and the second nitride layer 504. In some embodiments, etching the second oxide layer 505 is performed by a wet etching method. In some embodiments, the wet etching method includes an etchant including diluted HF.

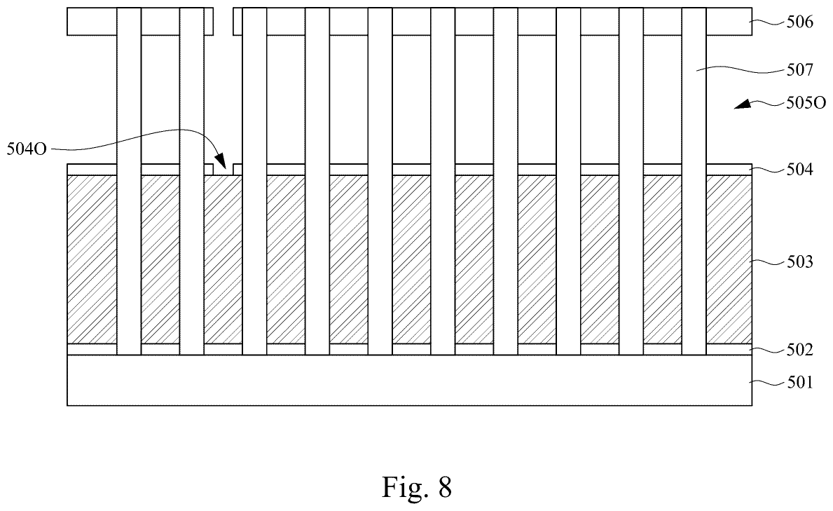

In FIG. 8, the method 400 further includes etching a portion of the second nitride layer 504 through the opening 506O of the third nitride layer 506 after the second oxide layer 505 is etched to expose the second nitride layer 504. After etching the portion of the second nitride layer 504, an opening 504O is formed in the second nitride layer 504 to expose the first oxide layer 503. In some embodiments, the etching is performed preferably by an anisotropic dry etching method.

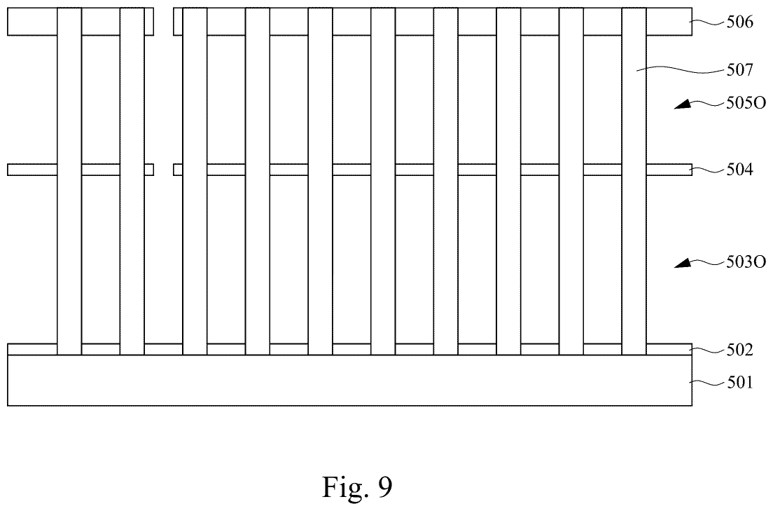

In FIG. 9, the method 400 further includes etching the first oxide layer 503 through the opening 504O of the second nitride layer 504. After etching the first oxide layer 503, an opening 503O between the first electrodes 507 is formed to expose the surfaces of the first electrodes 507. In some embodiments, etching the first oxide layer 503 is performed by a wet etching method. In some embodiments, the wet etching method includes an etchant including diluted HF.

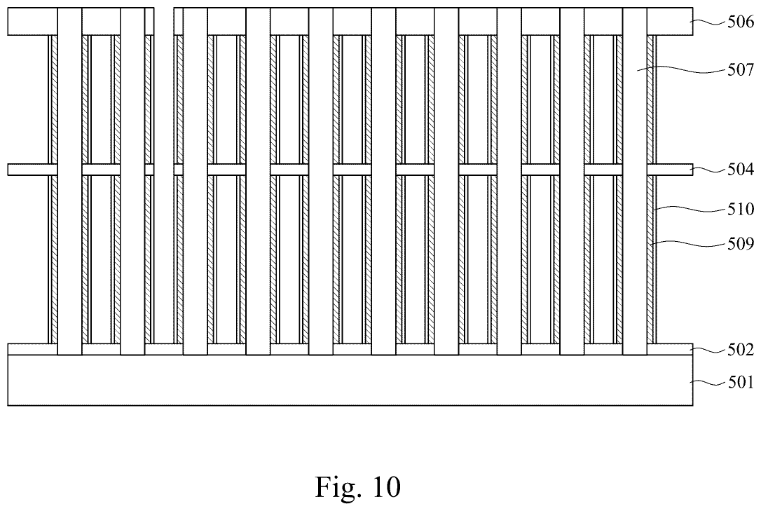

In FIG. 10, the method 400 further includes forming the dielectric layers 509 and the second electrodes 510 on the exposed surfaced of the first electrodes 507 to form the capacitors, in which the dielectric layers 509 are disposed between the first electrodes 507 and the second electrodes 510. In some embodiments, forming the dielectric layers 509 and the second electrodes 510 may be performed by any suitable method, for example, a chemical vapor deposition or a physical vapor deposition. In some embodiments, the dielectric layers 509 include any suitable dielectric materials used in the capacitors, and the second electrodes 510 include any suitable electrode materials used in the capacitors.

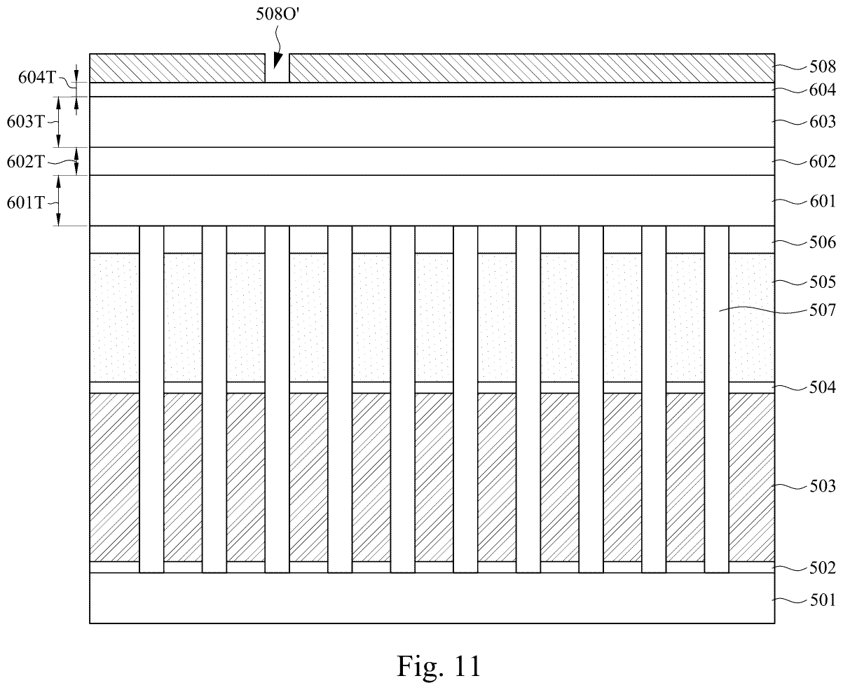

FIG. 11 provides a comparative embodiment 1 of using a Kodiak carbon hard mask 601 to etch the same structure as shown in FIG. 5. Since an absorbance of the Kodiak carbon hard mask 601 is large, when the photoresist layer 508 is formed on the Kodiak carbon hard mask 601 in order to perform the operations described above to etch the structure disposed below the Kodiak carbon hard mask 601, a correct position to form the opening in the photoresist layer 508 is hard to determine by using the light shining on the structure and measuring the reflected light. Therefore, an opening 508O′ may be formed in an incorrect position of the photoresist layer 508, for example, the opening 508O′ being above the first electrodes 507 or too close to the first electrodes 507, thereby damaging the first electrodes 507 and/or causing the first electrodes 507 to bend after performing the etching. Another drawback of the Kodiak carbon hard mask 601 is that a thickness 601T of the Kodiak carbon hard mask 601 is large in order to etch the structure including the high aspect ratios of the capacitors (or the structure including the large height of the first electrodes 507). For example, the thickness 601T of the Kodiak carbon hard mask 601 may be at least 200 nm. In addition, the Kodiak carbon hard mask 601 is usually used along with a Si-rich dielectric anti-reflective coating layer 602, a C-rich organic layer 603, and a Si-rich organic layer 604 when disposed below the photoresist layer 508. However, an absorbance of the Si-rich dielectric anti-reflective coating layer 602 is larger than the absorbance of the O-rich dielectric anti-reflective coating layer, such that the Si-rich dielectric anti-reflective coating layer 602 may be worse than the dielectric anti-reflective coating layer 202 being the O-rich dielectric anti-reflective coating layer when using the light to find the correct etch position. Moreover, a thickness 602T of the Si-rich dielectric anti-reflective coating layer 602 is at least 75 nm, a thickness 603T of the C-rich organic layer 603 is at least 200 nm, and a thickness 604T of the Si-rich organic layer 604 is at least 32 nm, such that a total thickness of the Kodiak carbon hard mask 601, the Si-rich dielectric anti-reflective coating layer 602, the C-rich organic layer 603, and the Si-rich organic layer 604 is much larger than a total thickness of the diamond-like carbon hard mask layer 201 (or the amorphous carbon hard mask layer 201′), the dielectric anti-reflective coating layer 202, and the bottom anti-reflective coating layer 203. In addition to increasing the cost, a larger thickness and more layers as an etch mask may also reduce the etch accuracy, especially when the pattern to etch requires a higher aspect ratio.

Table 1 summarizes the comparisons to form the diamond-like carbon hard mask layer 201 (or the amorphous carbon hard mask layer 201′) in the embodiment 1 and the Kodiak carbon hard mask 601 in the comparative embodiment 1. Table 2 summarizes the comparisons of the characteristics and the performance in the embodiment 1 and the comparative embodiment 1. The methods to form the diamond-like carbon hard mask layer 201 (or the amorphous carbon hard mask layer 201′) and the Kodiak carbon hard mask 601 were very different, as shown in Table 1, such that the characteristics and the performance of the diamond-like carbon hard mask layer 201 (or the amorphous carbon hard mask layer 201′) and the Kodiak carbon hard mask 601 were also different. Although both the diamond-like carbon hard mask layer 201 (or the amorphous carbon hard mask layer 201′) and the Kodiak carbon hard mask 601 had smaller stresses to avoid the etched pattern to bend and larger etch selectivities relative to the oxide material, the absorbance of the Kodiak carbon hard mask 601 was too large and the refractive index of the Kodiak carbon hard mask 601 was too small to affect using the light to find the correct etch position. In addition to being harder to find the correct etch position, the etch uniformity might be affected as well. For example, the three standard deviations (3σ) of the etch depth by using the Kodiak carbon hard mask 601 is larger than the three standard deviations of the etch depth by using the diamond-like carbon hard mask layer 201 (or the amorphous carbon hard mask layer 201′).

TABLE 1

| | | | Power | Power | | |
|---|---|---|---|---|---|---|
| | | | of low | of high | | Temper- |
| | | | frequency | frequency | Pressure | ature |
| | Precursor | Inert gas | (W) | (W) | (Torr) | (° C.) |
| Embodiment 1 | C₂H₂ | He and Ar | 2400 | 400 | 2.2 | 275 |
| Comparative | C₃H₆ | He and Ar | N/A | 2200 | 8.6 | 630 |
| embodiment 1 | | | | | | |

TABLE 2

| | | Refractive | | | |
|---|---|---|---|---|---|
| | Absorbance | index | Stress | Etch | Etch |
| | at 248 nm | at 248 nm | (MPa) | selectivity | uniformity |
| Embodiment 1 | 0.418 | 1.89 | −550 | 20:1 | 3σ = 1.2 nm |
| Comparative | 0.773 | 1.61 | −300 | 30:1 | 3σ = 1.57 nm |
| embodiment 1 | | | | | |

Table 3 summarizes the comparisons to form the diamond-like carbon hard mask layer 201 (or the amorphous carbon hard mask layer 201′) in the embodiment 1 and to form a similar but different layer in the comparative embodiment 2. As long as the method to form the layer was different than what is provided in the present disclosure to form the diamond-like carbon hard mask layer 201 (or the amorphous carbon hard mask layer 201′), the characteristics between such layer and the diamond-like carbon hard mask layer 201 (or the amorphous carbon hard mask layer 201′) might be much different, as shown in Table 4. For example, the stress of the layer formed in the comparative embodiment 2 was too large to cause the etched pattern to bend easily. The absorbance and the refractive index of the layer formed in the comparative embodiment 2 was also too large and too small, respectively, to affect using the light to find the correct etch position when using such layer as an etch mask.

TABLE 3

| | | | Power | Power | | |
|---|---|---|---|---|---|---|
| | Precursor, | Inert gas, | of low | of high | | Temper- |
| | flow rate | flow rate | frequency | frequency | Pressure | ature |
| | (SCCM) | (SCCM) | (W) | (W) | (Torr) | (° C.) |
| Embodiment 1 | C₂H₂, 340 | He, 3200 | 2400 | 400 | 2.2 | 275 |
| | | Ar, 8800 | | | | |
| Comparative | C₂H₂, 280 | He, 4000 | 2400 | 400 | 1.0 | 630 |
| embodiment 2 | | Ar, 11000 | | | | |

TABLE 4

| | | Refractive | | |
|---|---|---|---|---|
| | Absorbance | index | Stress | Etch |
| | at 248 nm | at 248 nm | (MPa) | selectivity |
| Embodiment 1 | 0.418 | 1.89 | −550 | 20:1 |
| Comparative | 0.525 | 1.79 | −900~−1000 | 30:1 |
| embodiment 2 | | | | |

The present disclosure provides methods of forming improved semiconductor structures by using an improved etch hard mask. For example, the etch hard mask has a smaller absorbance, such that the light shining on and reflected from the etch hard mask is not absorbed too much by the etch hard mask when using the light to find the correct etch position disposed below the etch hard mask. Therefore, the opening can be formed in a correct position in the photoresist layer disposed on the etch hard mask to align with the correct etch position. Moreover, since the absorbance of the etch hard mask is smaller, the etch position may be adjusted immediately using the light throughout the etching process. Finding the correct etch position improves the etch uniformity, avoids damaging the semiconductor structure, and avoids the etched pattern to bend easily, which is especially beneficial for etching with a higher aspect ratio.

The present disclosure is described in considerable detail in some embodiments, but other embodiments may also be feasible, so the description of the embodiments in the present disclosure is not intended to limit the scope and spirit of the claims attached. For one skilled in the art, the present disclosure may be modified and changed without deviating from the scope and spirit of the present disclosure. Such modifications and changes are intended to be covered by the present disclosure when they belong to the scope and spirit of the attached claims.

What is claimed is:

1. A method of forming a semiconductor structure, comprising:
forming a diamond-like carbon hard mask layer on a substrate, wherein an absorbance of the diamond-like carbon hard mask layer is smaller than or equal to 0.5;
forming a dielectric anti-reflective coating layer on the diamond-like carbon hard mask layer; and
forming a bottom anti-reflective coating layer on the dielectric anti-reflective coating layer.

2. The method of claim 1, wherein forming the diamond-like carbon hard mask layer comprises: providing C₂H₂ and an inert gas; and reacting the C₂H₂ to form the diamond-like carbon hard mask layer.

3. The method of claim 2, wherein a ratio of a flow rate of the C₂H₂ to a flow rate of the inert gas is from 1:20 to 1:50.

4. The method of claim 2, wherein a flow rate of the C₂H₂ is from 290 SCCM to 390 SCCM.

5. The method of claim 1, wherein forming the diamond-like carbon hard mask layer is performed at a pressure from 1.3 Torr to 3.1 Torr.

6. The method of claim 1, wherein forming the diamond-like carbon hard mask layer is performed at a temperature from 150° C. to 400° C.

7. The method of claim 1, wherein a stress of the diamond-like carbon hard mask layer is from −750 MPa to −350 MPa.

8. The method of claim 1, wherein a thickness of the diamond-like carbon hard mask layer is smaller than or equal to 150 nm.

9. The method of claim 1, wherein an etch selectivity of an oxide material relative to the diamond-like carbon hard mask layer is from 15:1 to 25:1.

10. A method of forming a semiconductor structure, comprising:
forming an amorphous carbon hard mask layer on first electrodes of capacitors on a substrate, wherein an absorbance of the amorphous carbon hard mask layer is smaller than or equal to 0.5, and an oxide layer is disposed between the first electrodes;
forming a photoresist layer having an opening on the amorphous carbon hard mask layer; and
etching the amorphous carbon hard mask layer through the opening of the photoresist layer.

11. The method of claim 10, wherein etching the amorphous carbon hard mask layer is performed till the oxide layer disposed between the first electrodes of the capacitors is exposed, and the method further comprises etching the oxide layer and forming dielectric layers and second electrodes on the first electrodes.

12. The method of claim 10, further comprising:
before or during forming the photoresist layer having the opening on the amorphous carbon hard mask layer, using a light shining on and reflecting from the amorphous carbon hard mask layer to determine positions of the first electrodes for aligning the opening of the photoresist layer with a position between two of the first electrodes.

13. The method of claim 10, wherein etching the amorphous carbon hard mask layer comprises using an anisotropic dry etching method.

14. The method of claim 10, wherein a stress of the amorphous carbon hard mask layer is from −750 MPa to −350 MPa.

15. The method of claim 10, wherein a thickness of the amorphous carbon hard mask layer is smaller than or equal to 150 nm.
